(19) United States
(12) Patent Application Publication
(10) Pub. No.: US 2026/0267228 A1
(43) Pub. Date: Sep. 10, 2026

(54) LITHOGRAPHY APPARATUS

(71) Applicant: Tokyo Electron Limited, Tokyo (JP)

(72) Inventors: Shinsuke TAKAKI, Koshi City (JP); Kouichi MIZUNAGA, Koshi City (JP); Yuma TABATA, Koshi City (JP); Ryusei NISHIMURA, Koshi City (JP)

(73) Assignee: Tokyo Electron Limited, Tokyo (JP)

(21) Appl. No.: 19/557,445

(22) Filed: Mar. 5, 2026

(30) Foreign Application Priority Data
Mar. 6, 2025 (JP) 2025-035357

(51) Int. Cl. G03F 7/36; B25J 11/00; G03F 7/38; H10P 72/30; H10P 72/76

(52) U.S. Cl. CPC G03F 7/36; B25J 11/0095; G03F 7/38; H10P 72/33; H10P 72/7602

(57) ABSTRACT

A lithography apparatus provided independently of an exposure apparatus includes a carry-in/out block having a placement section in which a receptacle accommodating multiple substrates is placed; and a processing block including multiple processing modules, each processing module each including a hot plate, a transfer space that extends in an apparatus width direction from a side of the carry-in/out block and is provided with a transfer arm, a plurality of heating blocks in which the multiple processing modules are arranged in the apparatus width direction including a front heating block at of a front side of the processing block and a rear heating block at a rear side of the processing block, the front heating block and the rear heating block face each other with the transfer space therebetween and an access opening for personnel into the transfer space.

### CROSS-REFERENCE TO RELATED APPLICATION

This application claims the benefit of Japanese Patent Application No. 2025-035357, filed on Mar. 6, 2025, the entire disclosures of which are incorporated herein by reference.

### TECHNICAL FIELD

The various aspects and embodiments described herein pertain generally to a lithography apparatus.

### BACKGROUND

A substrate processing system disclosed in Patent Document 1 includes a coating and developing apparatus and an exposure apparatus, which are provided separately, and an upward transfer mechanism that transfers a receptacle accommodating a substrate between the coating and developing apparatus and the exposure apparatus. In the coating and developing apparatus, an indexer block equipped with a receptacle placement table for placing the receptacle thereon, a resist block, and a development block are arranged in this order in a row. The resist block includes multiple resist coating modules stacked in multiple stages on one side, and multiple heating modules and cooling modules on the other side. Further, at the center of the resist block is located a resist transfer mechanism configured to transfer the substrate between the modules stacked on the two opposite sides of the resist block and placement sections located at the front and rear sides of the resist block.

Patent Document 1: Japanese Patent Laid-open Publication No. 2009-049053

### SUMMARY

In one exemplary embodiment, a lithography apparatus provided independently of an exposure apparatus includes a carry-in/out block having a placement section in which a receptacle accommodating multiple substrates is placed; and a processing block including multiple processing modules, each processing module including a hot plate, a transfer space that extends in an apparatus width direction from a side of the carry-in/out block and is provided with a transfer arm, a plurality of heating blocks in which the multiple processing modules are arranged in the apparatus width direction including a front heating block at of a front side of the processing block and a rear heating block at a rear side of the processing block, the front heating block and the rear heating block facing each other with the transfer space therebetween, and an access opening for personnel into the transfer space.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a plan view schematically illustrating a configuration of a lithography apparatus according to a first exemplary embodiment;

FIG. 2 is a longitudinal side view schematically illustrating a configuration of a processing block belonging to the lithography apparatus of FIG. 1;

FIG. 3 is a plan view schematically illustrating a configuration of a lithography apparatus according to a second exemplary embodiment;

FIG. 4 is a plan view schematically illustrating a configuration of a processing block belonging to the lithography apparatus of FIG. 3;

FIG. 5 is a longitudinal side view schematically illustrating the processing block belonging to the lithography apparatus of FIG. 3;

FIG. 6 is a longitudinal side view schematically illustrating a unit block belonging to the processing block of FIG. 4;

FIG. 7 is a partially enlarged plan view schematically illustrating a configuration of a lithography apparatus according to a third exemplary embodiment;

FIG. 8 is a plan view schematically illustrating a configuration of a lithography apparatus according to a fourth exemplary embodiment; and

FIG. 9 is a diagram illustrating an example in which the types of processing modules containing hot plates are different between a front heating block and a rear heating block.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, a lithography apparatus according to exemplary embodiments will be explained with reference to the accompanying drawings, which form a part thereof. In the present specification and the various drawings, parts having substantially the same functions and configurations will be assigned same reference numerals, and redundant descriptions thereof will be omitted.

### First Exemplary Embodiment

### <Lithography Apparatus>

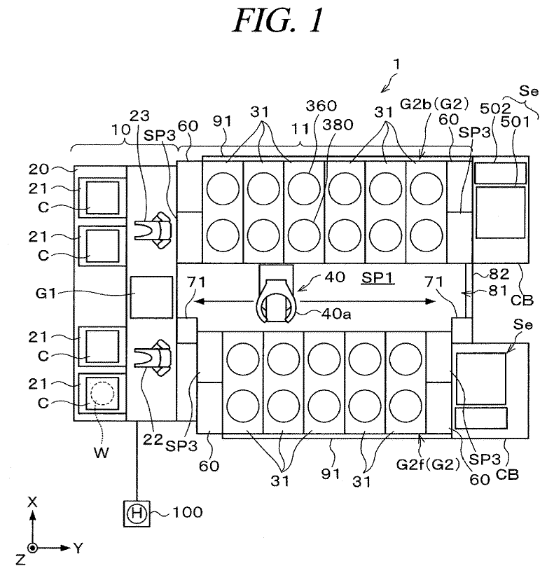

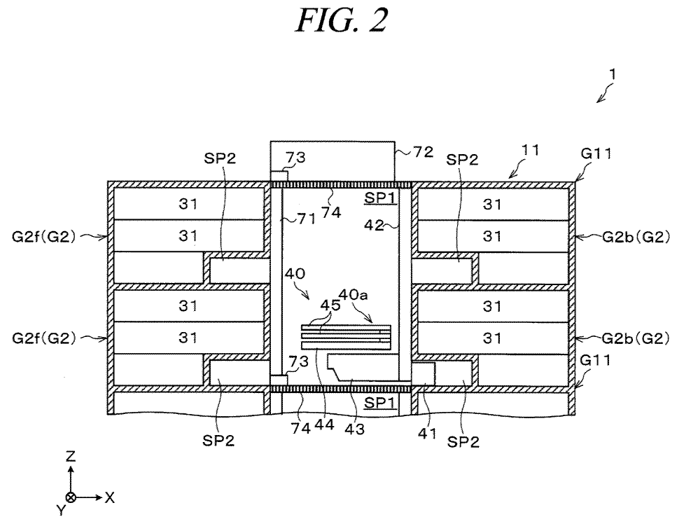

FIG. 1 is a plan view schematically illustrating a configuration of a lithography apparatus according to a first exemplary embodiment. FIG. 2 is a longitudinal side view schematically illustrating a configuration of a processing block to be described later. In the present disclosure, the “lithography apparatus” refers to an apparatus that performs at least some of a series of processes of lithography on a substrate such as a semiconductor wafer (hereinafter, simply referred to as “wafer”) to form a resist pattern on the substrate. The series of processes include a resist coating process of supplying a resist liquid onto the substrate to form the resist film, a post-exposure bake (PEB) process of heating the substrate after exposure to accelerate a chemical reaction within the resist film exposed into a preset pattern, a development process of developing the exposed resist film to form the resist pattern, and so forth.

The lithography apparatus 1 in FIG. 1 and FIG. 2 is an apparatus provided independently of an exposure apparatus that performs on a substrate an exposure process of exposing it into a preset pattern, and this lithography apparatus 1 includes a carry-in/out block 10 and a processing block 11. Specifically, the lithography apparatus 1 has a configuration in which the carry-in/out block 10 and the processing block 11 are arranged in an apparatus width direction (Y-axis direction) and connected as a single structure. In the illustrated example, only one processing block 11 is provided, but multiple processing blocks 11 may be arranged along the apparatus width direction (Y-axis direction).

Furthermore, another block (not shown) may be disposed between the carry-in/out block 10 and the processing block 11 to be adjacent to both blocks. Although the types of modules and equipment provided in the another block are not limited, it may include, by way of example, a wafer standby stage, a transfer arm, a processing module that performs a certain process, and an inspection module. The another block allows the wafer to be transferred between the carry-in/out block 10 and the processing block 11.

The carry-in/out block 10 is a block in which cassettes C are carried to/from the outside of the lithography apparatus 1. Each cassette C is a receptacle that accommodates a plurality of wafers W as substrates. That is, the wafers W are carried into and out of the carry-in/out block 10 on a cassette C basis.

A placement table 20 as a placement section is provided on the negative Y-axis side (left side in FIG. 1) of the carry-in/out block 10. On the placement table 20, multiple placement plates 21 for placing thereon the cassettes C when the cassettes C are carried to/from the outside of the lithography apparatus 1 are arranged along an apparatus depth direction (X-axis direction in FIG. 1).

In addition, the carry-in/out block 10 is provided with a transfer module 22 and a transfer module 23 between the placement table 20 and the processing block 11. In the carry-in/out block 10, the wafers W are transferred by the transfer module 22 or 23 between the cassette C placed on the placement table 20 and the processing block 11. To this end, each of the transfer modules 22 and 23 has a transfer arm configured to be movable in horizontal directions (X-and Y-axis directions), a vertical direction (Z-axis direction), and around a vertical axis (θ direction), for example.

At least one of the transfer modules 22 and 23 is capable of delivering the wafers W to/from the cassettes C, and is also capable of performing a wafer delivery operation with respect to the processing block 11. Here, the wafer delivery operation with respect to the processing block 11 refers to, for example, delivering the wafers W to/from a delivery block G1 equipped with a delivery module (not shown) accessible by a transfer arm 40a to be described later within the processing block 11. A plurality of such delivery modules may be arranged vertically in the delivery block G1. The delivery block G1 is disposed in the carry-in/out block 10, for example. Alternatively, the delivery block G1 may be disposed in the processing block 11.

The processing block 11 has multiple developing modules 31 as processing modules each including a hot plate. Also, the processing block 11 has a transfer space SP1 which extends in the apparatus width direction (Y-axis direction) from the carry-in/out block 10 side and is provided with a transfer arm 40a of a transfer module 40, which will be described further below.

Furthermore, a heating block G2 is provided at each of the front side (negative X-axis side) and the rear side (positive X-axis side) of the processing block 11, which face each other with the transfer space SP1 therebetween, when viewed from the top. Hereinafter, the heating block G2 provided on the front side will sometimes be referred to as “front heating block G2f,” and the heating block G2 provided on the rear side will sometimes be referred to as “rear heating block G2b.”

As shown in FIG. 1, in each heating block G2, a plurality of the developing modules 31 are arranged in the apparatus width direction (Y-axis direction). Furthermore, as illustrated in FIG. 2, a plurality of the developing modules 31 may also be arranged in the vertical direction (Z-axis direction) within each heating block G2; that is, the developing modules 31 may be stacked. In addition, the front heating block G2f itself and the rear heating block G2b itself may be provided in plurality, and the plurality of front heating blocks G2f and the plurality of rear heating blocks G2b may be stacked, respectively. In the illustrated example, the processing block 11 is vertically divided into multiple unit blocks G11, and a plurality of (specifically, two) front heating blocks G2f and a plurality of (specifically, two) rear heating blocks G2b are stacked in each unit block G11. Each unit block G11 has a ceiling wall at its upper portion and a bottom wall at its lower portion, and is partitioned from the outside by these ceiling and bottom walls. Alternatively, only one front heating block G2f and only one rear heating block G2b may be disposed in each unit block G11.

Furthermore, an accommodation space SP2 may be provided below each rear heating block G2b (specifically, below it on the transfer space SP1 side). The accommodation space SP2 may also be provided above each rear heating block G2b (specifically, above it on the transfer space SP1 side).

Likewise, an accommodation space SP2 may be provided below or above each front heating block G2f (specifically, below or above it on the transfer space SP1 side).

The developing module 31 develops the wafer W on which a resist film has been formed and which has been subjected to an exposure process, using a developing fluid including a weak acid gas. To elaborate, the developing module 31 develops the wafer W on which a metal-containing resist film has been formed and which has been subjected to an exposure process and a post-exposure bake process (PEB process), using the developing fluid. The exposure process here is a process of transferring a mask pattern by using exposure light, which is performed by an exposure apparatus.

Here, the metal-containing resist refers to a resist that contains a metal as a resist component, and does not mean a resist that contains a metal only as an impurity.

The metal-containing resist is a material of the resist film formed on a surface of the wafer W, and it contains a metal bonded to a ligand.

The metal as the component of this resist may be selected from, by way of non-limiting example, tin (Sn), tungsten (W), hafnium (Hf), zirconium (Zr), indium (In), tellurium (Te), antimony (Sb), nickel (Ni), cobalt (Co), titanium (Ti), tantalum (Ta), molybdenum (Mo), bismuth (Bi), iodine (I), germanium (Ge), and the group consisting of combinations of these, but is not limited thereto.

As an example of a reaction of the metal-containing resist, after the bond between the metal and the ligand is broken (i.e., the ligand dissociates), a condensation reaction occurs, during which metal atoms bond to each other via oxygen atoms to thereby form an oxide. The metal in this oxidized state is a stronger compound than before it becomes the oxide. The dissociation of the ligand occurs primarily through the exposure, and the condensation reaction occurs primarily through the heating after the exposure. As a result, the metal in the oxidized state exists in the resist film.

The weak acid gas mentioned above is, by way of non-limiting example, a weak carboxylic acid gas. The weak carboxylic acid gas may be, for example, a vapor of acetic acid. In the present disclosure, “weak acid” refers to an acid with an acid dissociation constant (pKa) value of 4 or higher (e.g., approximately 5). Further, the developing fluid containing the weak acid gas may include, for example, a vaporized substance, that is, a vapor of a mixed solution of the weak carboxylic acid and an organic solvent, and a carrier gas. The developing fluid containing the weak acid gas may also include a vaporized substance from the weak carboxylic acid alone, and a carrier gas. As a specific example, the weak carboxylic acid is acetic acid. The organic solvent is, for example, propylene glycol monomethyl ether acetate (PGMEA). The carrier gas is, for example, an inert gas such as a nitrogen gas or argon (Ar).

The developing module 31 includes, as shown in FIG. 1, a hot plate 360. The hot plate 360 is configured to support the wafer W and heat the wafer W positioned on it. The hot plate 360 is equipped with a heater (not shown), such as a resistance heater, embedded therein. The hot plate 360 has, for example, an approximately circular thick plate shape. For example, the temperature of the hot plate 360 is adjusted by controlling the heater by a controller 100 to be described later, whereby the wafer W positioned on the hot plate 360 by, for example, being supported by the hot plate 360 is heated to a preset temperature. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

The developing module 31 may also include a cooling plate 380. The cooling plate 380 has a temperature control member (not shown), such as cooling water or a Peltier element, embedded therein. The temperature of the cooling plate 380 is controlled and adjusted by, for example, the controller 100, whereby the temperature of the wafer W placed on the cooling plate 380 is regulated to a set temperature. The cooling plate 380 may be configured to support the wafer W to enable the transfer of the wafer W with respect to the hot plate 360.

As described above, the transfer arm 40a of the transfer module 40 is provided in the transfer space SP1. The transfer module 40 can transfer the wafer W to a preset module provided within or around the transfer space SP1.

The transfer module 40 includes, as illustrated in FIG. 2, a guide 41 extending along the apparatus width direction (Y-axis direction), and the transfer arm 40a configured to support the wafer W and move it in horizontal directions (X-and Y-axis directions), a vertical direction (Z-axis direction), and around a vertical axis (θ direction). The guide 41 constitutes at least a part of a moving mechanism that moves the transfer arm 40a.

The transfer arm 40a has a frame 42 that moves in the apparatus width direction (Y-axis direction) along the guide 41, an elevating body 43 that moves up and down along the frame 42, and a base 44 that rotates relative to the elevating body 43. Further, the transfer arm 40a has a fork 45. The fork 45 is an example of a movable substrate support configured to support the substrate, and it moves forward and backward with respect to the base 44.

The transfer module 40 and the transfer space SP1 are provided for each unit block G11. Therefore, when the front heating blocks G2f and the rear heating blocks G2b are respectively stacked in the unit block G11, the transfer module 40 is shared between the heating blocks G2 within the unit block G11.

Furthermore, when the two front heating blocks G2f and the two rear heating blocks G2b are stacked in the unit block G11, the guide 41 constituting the moving mechanism for moving the transfer arm 40a in that unit block G11 may be accommodated in, among the multiple accommodation spaces SP2, the accommodation space SP2 of the rear heating block G2b on the lower side. That is, when the heating blocks G2 are stacked as described above, the guide 41 may be accommodated in, among the multiple accommodation spaces SP2, the accommodation space SP2 farther from the boundary between the upper rear heating block G2b and the lower rear heating block G2b.

Furthermore, as shown in FIG. 1, side accommodation spaces SP3 and exhaust ducts 60 are provided at two opposite ends of a portion of the processing block 11 at the rear of the transfer space SP1 in the apparatus width direction (Y-axis direction).

Likewise, side accommodation spaces SP3 and exhaust ducts 60 are also provided at two opposite ends of a portion of the processing block 11 at the front of the transfer space SP1 in the apparatus width direction (Y-axis direction).

For example, electrical components related to the developing modules 31 are stored in the side accommodation spaces SP3.

The exhaust ducts 60 connect the developing modules 31 to an exhaust device (not shown) that evacuates the developing modules 31.

Furthermore, in the processing block 11, vertical ducts 71 are provided at respective portions that overlap with the two opposite ends of a front-side (X-axis side) end portion of the transfer space SP1 in the apparatus width direction (Y-axis direction), when viewed from the top. As illustrated in FIG. 2, each vertical duct 71 extends in the vertical direction (Z-axis direction) and is formed so as to span multiple unit blocks G11.

One end of the vertical duct 71 is connected to a fan filter unit (FFU) 72 disposed above the processing block 11, and the other end is connected to a horizontal duct 73. The horizontal duct 73 is provided for each unit block G11 and extends in the apparatus width direction (Y-axis direction) from the vertical duct 71. Furthermore, the horizontal duct 73 has a ULPA filter (not shown) inside.

Air blown from the FFU 72 flows through the vertical duct 71 into the horizontal duct 73, where the air is purified by the ULPA filter and supplied downwards from the horizontal duct 73.

Furthermore, a partition plate 74 is provided below the horizontal duct 73. This partition plate 74 constitutes the ceiling wall defining the transfer space SP1 of each unit block G11, and has therein a gas diffusion chamber (not shown) in which the air supplied from the horizontal duct 73 is diffused. Further, the partition plate 74 is provided with, in its entire bottom surface, a multiple number of discharge openings (not shown) for discharging the air diffused in the gas diffusion chamber into the transfer space SP1.

The air, which has passed through the ULPA filter of the horizontal duct 73 and thus been purified free of particles, flows into the gas diffusion chamber of the partition plate 74 and is discharged downwards through the discharge openings. In this way, a downward flow of the purified air is formed in each transfer space SP1.

Furthermore, as the developing module 31 around the transfer space SP1 is evacuated, a flow of the purified air heading toward the inside of the developing module 31 from the transfer space SP1 is formed.

Separate FFUs 72 may be respectively provided for the vertical duct 71 on one side in the apparatus width direction (Y-axis direction) and the vertical duct 71 on the other side.

Furthermore, the horizontal duct 73 may be divided into two in the apparatus width direction (Y-axis direction), and each may be connected to the nearby vertical duct 71.

In the present exemplary embodiment, the number of the vertical ducts 71 is two, and each vertical duct 71 is provided at the front-side (negative X-axis side) end portion of the transfer space SP1, as stated above. Furthermore, in the present exemplary embodiment, the sum of the lengths of the two vertical ducts 71 and the length of the front heating block G2f in the apparatus width direction (Y-axis direction) is set to be equal to the length of the rear heating block G2b in the apparatus width direction. Therefore, in the present exemplary embodiment, the number of the developing modules 31 mounted in the heating blocks G2 differs between the front heating block G2f and the rear heating block G2b, and the rear heating block G2b accommodates more developing modules 31. Furthermore, due to this difference in the number of mounted developing modules, the positions of the developing modules 31 in the apparatus width direction (Y-axis direction) differ between the front heating block G2f and the rear heating block G2b.

Here, the two vertical ducts 71 may be located at rear-side (positive X-axis side) end portions of the transfer space SP1, respectively. Alternatively, one of the two vertical ducts 71 may be located at the rear-side (positive X-axis side) end portion of the transfer space SP1, whereas the other may be located at the front-side (negative X-axis side) end portion of the transfer space SP1. In this case, the same number of developing modules 31 may be mounted in the front heating block G2f and the rear heating block G2b, and the mutually corresponding developing modules 31 of the respective heating blocks G2 may face each other with the transfer space SP1 therebetween.

Furthermore, as illustrated in FIG. 1, the processing block 11 is provided with an access opening 81 for personnel (workers) into the transfer space SP1. For example, the access opening 81 is located on the opposite side (positive Y-axis side in the drawing) of the processing block 11 from the carry-in/out block 10. A door 82 is configured to open and close the access opening 81. A worker that has entered the transfer space SP1 through the access opening 81 performs maintenance work on, for example, the transfer arm 40a within the transfer space SP1 or the modules surrounding the transfer space SP1.

The depth (length in the X-axis direction) of the transfer space SP1 is set sufficiently great to allow the worker to perform the maintenance work described above. By way of example, the depth of the transfer space SP1 is set to correspond to two sheets of wafers W each having a diameter of 300 mm.

The lithography apparatus 1 also has chemical boxes CB on both the front side (negative X-axis side) and the rear side (positive X-axis side) thereof. Each chemical box CB accommodates, for example, a set Se consisting of a vaporizer 501 and a concentration sensor 502. The set Se is provided for each developing module 31.

The vaporizer 501 is an example of a fluid generator that generates the developing fluid from a developing liquid. Specifically, the vaporizer 501 vaporizes, for example, a mixed solution of an acid and an organic solvent as the developing liquid, thereby generating the developing fluid.

The concentration sensor 502 measures the concentration of the weak acid in the developing fluid generated by the vaporizer 501.

The vaporizer 501 in the chemical box CB and the developing module 31 in the heating block G2 corresponding thereto are connected by a developing fluid supply line 91. The developing fluid supply line 91 for the developing modules 31 in the front heating block G2f is located along a front surface (the surface on the negative X-axis side) of the front heating block G2f, and the developing fluid supply line 91 for the developing modules 31 in the rear heating block G2b is located along a rear surface (the surface on the positive X-axis side) of the rear heating block G2b.

Further, the chemical boxes CB are positioned so that the worker can enter and exit through the access opening 81 without being obstructed. Specifically, the chemical boxes CB are respectively provided on the front side (negative X-axis side) and the rear side (positive X-axis side) of the lithography apparatus 1 so as to form a recess extending in the apparatus width direction (Y-axis direction) from a side (positive Y-axis side) opposite to the carry-in/out block 10 toward the access opening 81.

A bottle (not shown) storing an acid (specifically, acetic acid) as a source of the developing liquid may be housed inside each chemical box CB.

The above-described lithography apparatus 1 is provided with at least one controller 100. The controller 100 processes computer-executable instructions that cause the lithography apparatus 1 to perform various processes described in the present disclosure. The controller 100 may be configured to control the individual components of the lithography apparatus 1 to perform the various processes described herein. In one exemplary embodiment, a part or the whole of the controller 100 may be included in the lithography apparatus 1. The controller 100 may include a processor, a storage, and a communication interface. The controller 100 may be implemented by, for example, a computer. The processor may be configured to read from the storage a program that provides logic or routines that enable various control operations, and to execute the read program to perform the various control operations. This program may be previously stored in the storage or may be acquired via a medium when necessary. The acquired program is stored in the storage, and read from the storage by the processor to be executed. The medium may be any of various computer-readable recording media H, or a communication line connected to the communication interface. The recording medium may be transitory or non-transitory. The processor may be a CPU (Central Processing Unit) or one or more circuits. The storage may include a RAM (Random Access Memory), a ROM (Read Only Memory), a HDD (Hard Disk Drive), a SSD (Solid State Drive), or a combination thereof. The communication interface may communicate with the lithography apparatus 1 via the communication line such as a LAN (Local Area Network).

### <Example of Processing Sequence>

Now, an example of a processing sequence performed by the lithography apparatus 1 will be explained.

### (Process S1)

First, the wafers W are carried into the lithography apparatus 1.

Specifically, the cassette C accommodating the plurality of wafers W is carried into the carry-in/out block 10 of the lithography apparatus 1 and placed on the placement plate 21. Each wafer W stored in the cassette C has the metal-containing resist film formed thereon and has undergone the exposure process and the post-exposure bake (PEB) process. Then, each wafer W in the cassette C is sequentially taken out by the transfer module 22 or 23 and transferred to the delivery module in the delivery block G1.

### (Process S2)

Subsequently, the wafer W is developed in the developing module 31 by the developing fluid whose weak acid concentration has been adjusted.

As a specific example, the wafer W in the delivery module of the delivery block G1 is first transferred into the developing module 31 by the transfer arm 40a. The wafer W is then placed on the hot plate 360.

Thereafter, the developing fluid with the adjusted temperature and weak acid concentration is supplied from the set Se, which includes the vaporizer 501 and the like, into the developing module 31. As a result, the wafer W heated by the hot plate 360 is exposed to the acid atmosphere containing the weak acid gas in the developing module 31. When the metal-containing resist film on the wafer W is exposed to the acid atmosphere, an unexposed portion of the resist film reacts with the weak acid gas, decomposing into smaller molecules. Furthermore, when the wafer W is heated, the unexposed portion of the metal-containing resist film on the wafer W, which has been decomposed into smaller molecules through the reaction with the weak acid gas, sublimate, thereby forming the metal-containing resist pattern. For example, if the weak acid gas is the acetic acid gas and the metal-containing resist contains tin as the metal, tin acetate will sublimate.

The supply of the developing fluid into the developing module 31 is stopped upon a lapse of a set time after started, which ends the process S2.

### (Process S3)

The wafer W is then carried out from the lithography apparatus 1.

Specifically, the wafer W is transferred by the transfer arm 40a to the delivery module in the delivery block G1, and then transferred to the cassette C on the designated placement plate 21 by the transfer module 22 or 23 in the carry-in/out block 10. In this way, the series of processes of the processing sequence are completed.

### <Major Effects of Present Exemplary Embodiment>

As described above, in the present exemplary embodiment, the lithography apparatus 1 is provided independently of the exposure apparatus. The lithography apparatus 1 is equipped with the carry-in/out block 10 including the placement table 20 on which the cassette C is placed, and the processing block 11 including the multiple developing modules 31 as the processing modules each having the hot plate and the transfer space SP1 extending in the apparatus width direction (Y-axis direction) from the carry-in/out block 10 side and provided with the transfer arm 40a. Furthermore, the heating blocks G2, each provided with the plurality of developing modules 31 arranged in the apparatus width direction (Y-axis direction), are disposed on the front side (negative X-axis side) and the rear side (positive X-axis side) of the processing block 11, facing each other with the transfer space SP1 therebetween. Therefore, as compared to a case where the heating blocks G2 are provided only on the front or rear side, more processing modules (specifically, developing modules 31) including the hot plates can be mounted in the lithography apparatus 1. Furthermore, the processing block 11 does not include a spin-coating module such as a resist coating module that forms the resist film on the wafer W. Therefore, as compared to a case where the spin-coating module is mounted on either the front or rear side, the lithography apparatus 1 can accommodate more processing modules (specifically, the developing modules 31) including the hot plates. Therefore, by using the lithography apparatus 1, the processing using the hot plate, such as a development process by the developing modules 31, can be performed intensively. Therefore, according to the present exemplary embodiment, it is possible to improve the usability of the lithography apparatus for a user who wishes to perform a high-throughput processing using the hot plate.

Furthermore, in the lithography apparatus 1, the processing block 11 has the access opening 81 for personnel into transfer space SP1. Therefore, the personnel (worker) that has entered the transfer space SP1 through the access opening 81 can perform the maintenance work on the lithography apparatus 1. That is, the maintainability of the lithography apparatus 1 may be improved. Therefore, according to the present exemplary embodiment, the usability of the lithography apparatus can be improved from this perspective as well.

Moreover, the structure of the lithography apparatus 1 can be converted into a so-called in-line system by, for example, omitting the component connected to the opposite side of the processing block 11 from the carry-in/out block 10 (in the present exemplary embodiment, the chemical box CB) and connecting an exposure apparatus to the same position.

### Second Exemplary Embodiment

### <Lithography Apparatus>

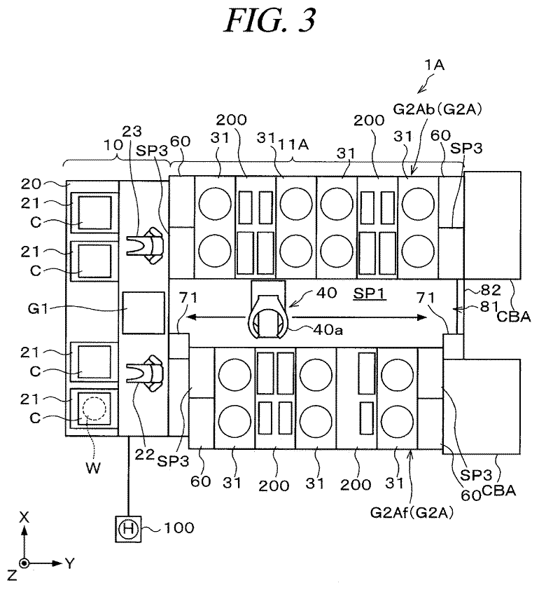

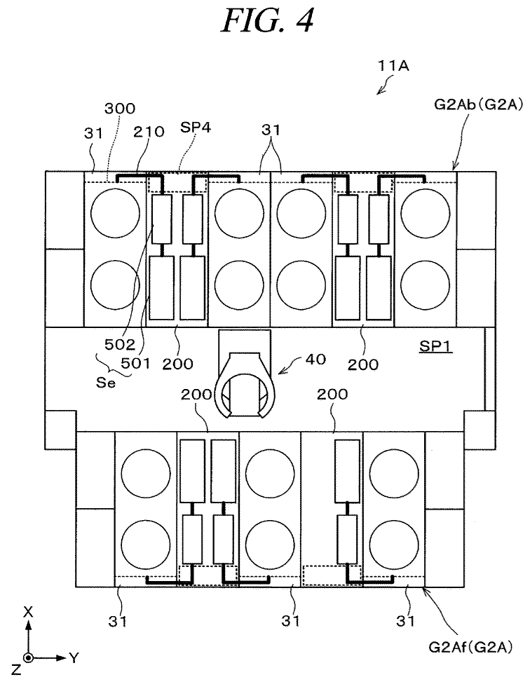

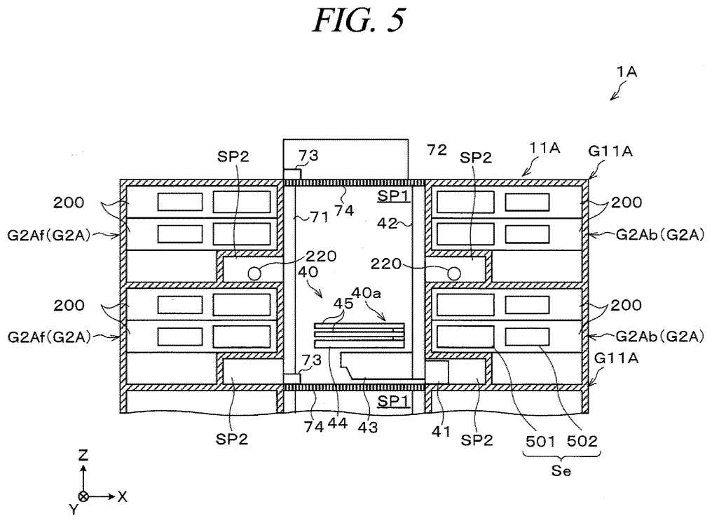

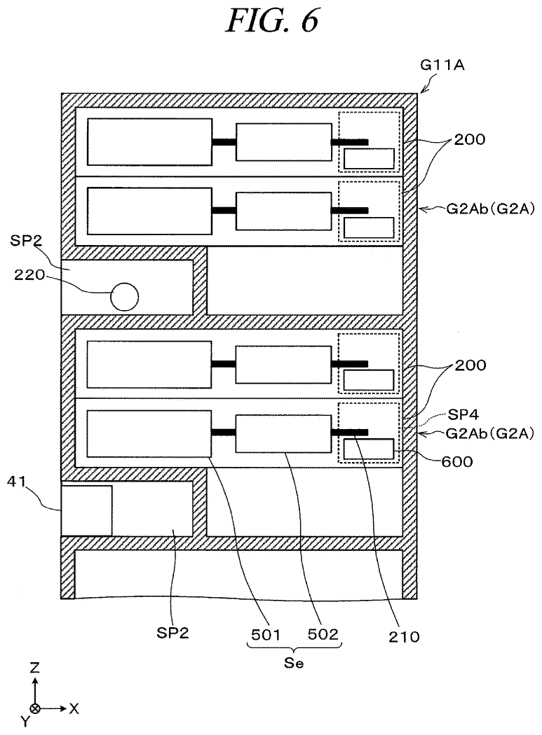

FIG. 3 is a plan view schematically illustrating a configuration of a lithography apparatus according to a second exemplary embodiment. FIG. 4 and FIG. 5 are a plan view and a longitudinal side view, respectively, schematically illustrating a configuration of a processing block belonging to the lithography apparatus of FIG. 3. Further, in FIG. 3, some of the components of the processing block shown in FIG. 4 are omitted. FIG. 6 is a longitudinal side view schematically illustrating a configuration of a unit block included in the processing block shown in FIG. 4. In FIG. 5, some of the components of the unit block shown in FIG. 6 are omitted.

A lithography apparatus 1A in FIG. 3, like the lithography apparatus 1 shown in FIG. 1, etc., includes a processing block 11A that has multiple developing modules 31 and a transfer space SP1. Furthermore, like the processing block 11 of the lithography apparatus 1 shown in FIG. 1, etc., the processing block 11A is provided with heating blocks G2A on its front side (negative X-axis side) and rear side (positive X-axis side) that face each other with the transfer space SP1 therebetween, when viewed from the top. Like the heating block G2 of the lithography apparatus 1 shown in FIG. 1, etc., the heating block G2A is provided with a plurality of the developing modules 31 arranged in the apparatus width direction (Y-axis direction).

However, unlike the heating block G2, the heating block G2A has vaporization regions 200 as fluid generation regions between the developing modules 31 arranged in the apparatus width direction (Y-axis direction). To elaborate, in the heating block G2A on the front side (hereinafter, sometimes referred to as “front heating block G2Af”), the vaporization regions 200 are provided between the first and second developing modules 31 and between the second and third developing modules 31 from the negative side in the apparatus width direction. In addition, in the heating block G2A on the rear side (hereinafter, sometimes referred to as “rear heating block G2Ab”), the vaporization regions 200 are provided between the first and second developing modules 31 and between the third and fourth developing modules 31 from the negative side in the apparatus width direction. Each vaporization region 200 is disposed to fit in a space having the same dimensions as one developing module 31.

In the heating block G2A, as shown in FIG. 4, vaporizers 501 serving as fluid generators are provided on two opposite sides within each vaporization region 200 in the apparatus width direction (Y-axis direction). Specifically, sets Se each consisting of the vaporizer 501 and a concentration sensor 502 are provided. In the illustrated example, the vaporizer 501 is provided on the transfer space SP1 side in the heating block G2A, but it may be provided on the opposite side of the heating block G2A from the transfer space SP1.

Furthermore, in the heating block G2A, a developing fluid from each vaporizer 501 is supplied to the developing module 31 which faces that corresponding vaporizer 501 in the apparatus width direction (Y-axis direction). That is, in the heating block G2A, each vaporizer 501 is connected to the developing module 31 facing it in the apparatus width direction (Y-axis direction) by a developing fluid supply line 210. Specifically, each vaporizer 501 is connected to the adjacent developing module 31 facing it in the apparatus width direction (Y-axis direction) via the developing fluid supply line 210 that is provided with the corresponding concentration sensor 502.

With this configuration, the length of the developing fluid supply line 210 led to the developing module 31 can be shortened, so that the controllability and responsiveness of the acid concentration in the developing fluid supplied to the developing module 31 can be improved. Further, this configuration also suppresses the developing fluid supply line 210 to the developing module 31 from becoming too long, while allowing the length of this supply line 210 to be uniform among the developing modules 31. Therefore, in addition to improving the controllability and responsiveness, it is possible to reduce non-uniformity in the acid concentration in the supplied developing fluid (that is, non-uniformity in development results) among the developing modules 31.

By establishing one-to-one correspondence between the vaporizer and the developing module, uniformity of the development process can be achieved. When the vaporizer is shared among the developing modules, if a problem occurs in the vaporizer, operation of multiple developing modules may be stopped. However, by establishing the one-to-one correspondence between the vaporizer and the developing module as in the present exemplary embodiment, even if the problem occurs in one vaporizer, the other developing modules not corresponding to the problematic vaporizer can continue to operate, thereby improving the productivity.

Further, in the rear heating block G2Ab, the sets Se are provided on two opposite sides within each vaporization region 200 in the apparatus width direction (Y-axis direction). In contrast, in the front heating block G2Af, due to a difference in the number of the developing modules 31 mounted, the set Se is provided only on one side (positive Y-axis side) in the apparatus width direction within the vaporization region 200 located between the second and third developing modules 31 from the negative side in the apparatus width direction, as illustrated in FIG. 3.

Furthermore, since the set Se is disposed in the heating block G2A, the chemical box CBA is not provided with the set Se, and the developing fluid supply line 91 is omitted.

In addition, the same as in the heating block G2, the multiple developing modules 31 may be arranged in the vertical direction (Z-axis direction), i.e., stacked in each heating block G2A. In this case, as shown in FIG. 5, the vaporizers 501 (specifically, the sets Se) and the vaporization regions 200 are also stacked so that the vaporizers 501 and the developing modules 31 as the destinations of the developing fluid face each other in the apparatus width direction (Y-axis direction). In the illustrated example, the heating blocks G2A are stacked in each unit block G11A, and the vaporizers 501 (specifically, the sets Se) and the vaporization regions 200 are stacked in each heating block G2A.

The vaporizers 501 of each unit block G11A are connected via a liquid supply line 220 to a bottle (not shown) storing an acid (specifically, acetic acid) as a source of a developing liquid. This bottle of the acid is provided in, for example, the chemical box CBA.

Furthermore, when two heating blocks G2A are stacked in the unit block G11A, the liquid supply line 220 may be accommodated in, among the aforementioned multiple accommodation spaces SP2, the accommodation space SP2 of the upper heating block G2A within this unit block G11A. That is, when the heating blocks G 2A are stacked as described above, the liquid supply line 220 within the unit block G11A may be accommodated, among the multiple accommodation spaces SP2, in the accommodation space SP2 which is closer to the boundary between the upper heating block G2A and the lower heating block G 2A. In this case, the developing fluid is distributed from the liquid supply line 220 accommodated in the accommodation space SP2 closer to the boundary to the heating block G2A above the accommodation space SP2 and the heating block G2A below it.

With this configuration, the following effects are achieved when each heating block G2A has the accommodation space SP2 for the purposes of uniformizing the external appearance, the transfer arm 40a is shared among the stacked heating blocks G2A within the unit block G11A, and the guide 41 constituting the moving mechanism of the transfer arm 40a is housed only in the accommodation space SP2 of the rear heating block G2Ab on the lower side.

That is, as a result of sharing the transfer arm 40a, among the multiple accommodation spaces SP2 in the unit block G11A, those not used when the vaporization regions 200 are not provided, such as those not used to accommodate the guide 41, can be effectively utilized.

The liquid supply line 220 housed in the accommodation space SP2 may be shared by some or all of the vaporizers 501 in the unit block G11A, or may be provided for each vaporizer 501.

The accommodation space SP2, which accommodates the liquid supply line 220, may also house therein power cables and signal lines for modules such as the vaporizer 501 provided in the vaporization region 200.

By arranging the liquid supply lines in the accommodation space at the boundary of the blocks, the uniformity can be achieved between the stacked blocks. If a problem occurs with any of the stacked blocks, the block can be replaced without disturbing the liquid supply lines, allowing for the modular structure.

As stated above, in the heating block G2A, each vaporizer 501 is connected to the developing module 31 facing it in the apparatus width direction (Y-axis direction) by the developing fluid supply line 210.

As shown in FIG. 4, the developing fluid supply line 210 reaches from the vaporizer 501 to a portion of the developing module 31 on the opposite side from the transfer space SP1 through a space SP4 in the vaporization region 200 on the opposite side from the transfer space SP1.

As shown in FIG. 6, the space SP4 is a room where an extension duct 600, which serves as an exhaust line connecting the developing module 31 and the exhaust duct 60 (see FIG. 3), is located. The developing fluid supply line 210 is disposed in a portion of the space SP4 where the extension duct 600 is not located. For example, while the extension duct 600 is located in a lower portion of the space SP4, the developing fluid supply line 210 is located in an upper portion of the space SP4. By arranging the developing fluid supply line 210 in this manner, the space SP4 can be effectively utilized.

Furthermore, as shown in FIG. 4, the developing fluid supply line 210 reaches the portion of the developing module 31 on the opposite side from the transfer space SP1, and then is connected to a processing vessel 300 of the developing module 31. The processing vessel 300 is a housing that houses the hot plate 360 and the cooling plate 380. A connection portion of the developing fluid supply line 210 in the processing vessel 300 is, for example, the center in the apparatus width direction (Y-axis direction) on the opposite side from the transfer space SP1.

The connection portion of the developing fluid supply line 210 in the processing vessel 300 may be located on the side of the corresponding vaporizer 501. However, by locating it at the center in the apparatus width direction (Y-axis direction) on the opposite side from the transfer space SP1, the following effects are achieved. That is, the connection portion of the developing fluid supply line 210 in the processing vessel 300 can be located at the same position regardless of its positional relationship with respect to the vaporizer 501 as the developing fluid source, thereby allowing the multiple developing modules 31 in the lithography apparatus 1A to have the uniform external appearance.

Moreover, the structure of the lithography apparatus 1A can be converted into a so-called in-line system by connecting an exposure apparatus to a portion of the processing block 11A on the opposite side from the carry-in/out block 10.

### Third Exemplary Embodiment

### <Lithography Apparatus>

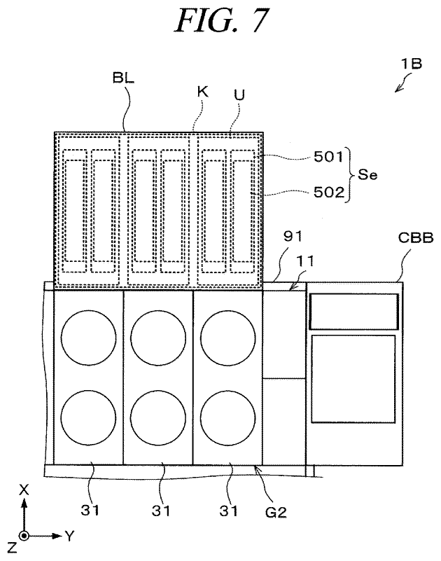

FIG. 7 is a partially enlarged plan view schematically illustrating a configuration of a lithography apparatus according to a third exemplary embodiment.

A lithography apparatus 1B in FIG. 7 has an extension block BL. The extension block BL accommodates a vaporizer 501, specifically, a set Se of the vaporizer 501 and a concentration sensor 502. More specifically, the extension block BL has an accommodation space K, and two sets Se are combined into a single unit U and accommodated in the same accommodation space K. The vaporizer 501 and the concentration sensor 502 constituting each set Se are, for example, stacked on top of each other.

The extension block BL is located adjacent to the rear side (positive X-axis side) of a processing block 11 in the apparatus depth direction (X-axis direction). Alternatively, the extension block BL may be located adjacent to the front side (negative X-axis side) of the processing block 11 in the apparatus depth direction, or adjacent to both the front side and the rear side of the processing block 11 in the apparatus depth direction.

Furthermore, among developing modules 31 in the processing block 11, those located at an end portion of the processing block 11 on the opposite side (positive Y-axis side) from the carry-in/out block 10 are supplied with a developing fluid from the vaporizer 501 in the extension block BL. The other developing modules 31 are supplied with the developing fluid from the vaporizers 501 accommodated in a chemical box CBB via the developing fluid supply line 91.

Furthermore, the extension block BL is provided only in a region of the processing block 11 that overlaps the positive Y-axis end portion of the processing block 11, where the developing modules 31 as the destination of the developing fluid are located, when viewed from the apparatus depth direction (X-axis direction), corresponding to the position of the developing modules 31 to which the developing fluid is supplied.

This allows maintenance of modules in the processing block 11 where no extension block BL is provided (for example, the developing modules 31 to which the developing fluid is supplied from the chemical box CBB) to be performed in the same manner as in the case where the extension block BL is not present.

Further, a portion of the developing fluid supply line 91 used to supply the developing fluid from the chemical box CBB may be located inside the extension block BL.

When the developing modules 31 to which the developing fluid is supplied are stacked, the accommodation spaces K for accommodating the sets Se including the vaporizers 501 may also be stacked in the extension block BL. In this case, each accommodation space K is located at the same height as the heating block G2 accommodating the developing module 31 to which the developing fluid is supplied from the set Se housed in that accommodation space K. Specifically, the developing fluid is supplied from the unit U housed in each accommodation space K to two stacked developing modules 31. However, the accommodation space K is stacked so that the unit U housed therein faces only the lower developing module 31 to which the developing fluid is supplied, not the upper developing module 31 to which the developing fluid is supplied.

Furthermore, in the extension block BL, a partition wall that separates the extension block BL from the processing block 11 (specifically, the heating block G2) is configured to be movable along the apparatus width direction (Y-axis direction). The partition wall is configured to open the inside of the processing block 11 (specifically, the inside of the heating block G2) to the extension block BL by being moved in this way.

The vaporizer 501 in the extension block BL is connected to a bottle (not shown) storing an acid (specifically, acetic acid) as a source of the developing liquid. This bottle of the acid is provided in, for example, the chemical box CBB.

When performing the maintenance on the developing module 31 to which the developing fluid is supplied from the extension block BL in the lithography apparatus 1B, an outer wall defining the accommodation space K of the extension block BL corresponding to the developing module 31 as a target of the maintenance is first separated, thereby opening the accommodation space K.

Then, the aforementioned partition wall is moved along the apparatus width direction (Y-axis direction), and the heating block G2 in which the developing module 31 as the target of the maintenance is accommodated is opened toward the extension block BL.

Then, the worker performs a maintenance work through a space in the extension block BL located above the set Se corresponding to the developing module 31 as the target of the maintenance. Here, the set Se may be separated before the maintenance.

In addition, in the above-describe exemplary embodiment, among the developing modules 31 in the processing block 11, it is the developing modules 31 located at the end portion of the processing block 11 on the opposite side (positive Y-axis side) from the carry-in/out block 10 that are supplied with the developing fluid from the vaporizers 501 within the extension block BL. Furthermore, when viewed from the apparatus depth direction (X-axis direction), the extension block BL is provided only in the region that overlaps the positive Y-axis end portion of the processing block 11, where the developing modules 31 as the destination of the developing fluid are provided. Alternatively, among the developing modules 31 in the processing block 11, it may be the developing modules 31 located at an end portion of the processing block 11 on the carry-in/out block 10 side (negative Y-axis side) that are supplied with the developing fluid from the vaporizers 501 within the extension block BL. The extension block BL may be provided only in a region overlapping the negative Y-axis end portion of the processing block 11, where the developing modules 31 to which the developing fluid is supplied are located, when viewed from the apparatus depth direction (X-axis direction). Still alternatively, among the developing modules 31 in the processing block 11, the developing modules 31 to which the developing fluid is supplied from the vaporizers 501 within the extension block BL may be provided at both the positive and negative Y-axis end portions of the processing block 11, respectively. When viewed from the apparatus depth direction (X-axis direction), the extension block BL may be provided in each of a region overlapping the positive Y-axis end portion of the processing block 11 and a region overlapping the negative Y-axis end portion of the processing block 11, where the developing modules 31 as the destinations of developing fluid are located.

### Fourth Exemplary Embodiment

### <Lithography Apparatus>

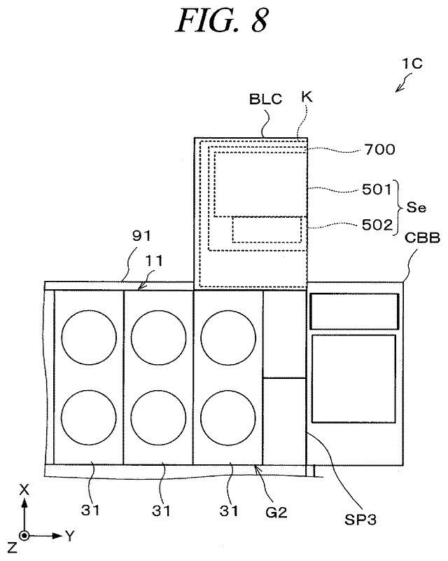

FIG. 8 is a plan view schematically illustrating a configuration of a lithography apparatus according to a fourth exemplary embodiment.

Like the lithography apparatus 1B in FIG. 7, a lithography apparatus 1C in FIG. 8 has an extension block BLC that accommodates a vaporizer 501. Specifically, the extension block BLC houses a set Se consisting of the vaporizer 501 and a concentration sensor 502. More specifically, the extension block BLC has an accommodation space K, and the vaporizer 501 and the concentration sensor 502 constituting the one set Se are housed in the same accommodation space K. The vaporizers 501 and concentration sensors 502 constituting the one set Se are arranged side by side in the apparatus depth direction (X-axis direction).

The extension block BLC is located adjacent to the rear side (positive X-axis side) of a processing block 11 in the apparatus depth direction (X-axis direction). Alternatively, the extension block BLC may be located adjacent to the front side (negative X-axis side) of the processing block 11 in the apparatus depth direction, or adjacent to both the front side and the rear side of the processing block 11 in the apparatus depth direction.

Further, among developing modules 31 in the processing block 11, the developing module 31 at an end portion on the opposite side (positive Y-axis side) from the carry-in/out block 10 is supplied with a developing fluid from the vaporizer 501 in the extension block BLC. The other developing modules 31 are supplied with the developing fluid via a developing fluid supply line 91 from the vaporizer 501 accommodated in a chemical box CBB.

Here, a portion of the developing fluid supply line 91 used to supply the developing fluid from the chemical box CBB may be located within the extension block BLC.

In the extension block BLC, multiple accommodation spaces K, each of which houses the set Se including the vaporizer 501, are stacked. Each accommodation space K is located at the same height as a heating block G2 accommodating the developing module 31 to which the developing fluid is supplied from the set Se housed in that accommodation space K. Specifically, each accommodation space K is positioned so as to face the developing module 31 as a destination of the developing fluid from the set Se housed therein in the apparatus depth direction (X-axis direction).

Furthermore, the extension block BLC supports the vaporizer 501 housed therein in a movable manner in the apparatus width direction (Y-axis direction). Specifically, the extension block BLC has a placement section 700 in which the set Se including the vaporizer 501 is placed and supported, and this placement section 700 is configured to be movable in the apparatus width direction (Y-axis direction). This configuration allows for adjustment of an overlapping amount of the placement section 700 with respect to the developing module 31 to which the developing fluid is supplied from the vaporizer 501 supported on the placement section 700, when viewed from the apparatus depth direction (X-axis direction). Specifically, when viewed from the apparatus depth direction (X-axis direction), the overlapping amount with the developing module 31 to which the developing fluid is supplied from the vaporizer 501 supported on the placement section 700 and with a side accommodation space SP3 is adjustable.

The placement section 700 is moved between, for example, a processing position, a routine maintenance position, and a major maintenance position.

When the placement section 700 is positioned at the processing position, the set Se placed in the placement section 700 and the placement section 700 itself overlap with the corresponding developing module 31 and the side accommodation space SP3, when viewed from the apparatus depth direction (X-axis direction). Furthermore, when the placement section 700 is positioned at the processing position, the set Se placed in the placement section 700 and the placement section 700 itself do not overlap with a block (chemical box CBB in the illustrated example) adjacent in the apparatus width direction (Y-axis direction) to the heating block G2 in which the corresponding developing module 31 is provided, when viewed from the apparatus depth direction (X-axis direction).

When the placement section 700 is located at the routine maintenance position as well, the set Se placed in the placement section 700 and the placement section 700 itself overlap with the corresponding developing module 31 and the side accommodation space SP3, when viewed from the apparatus depth direction (X-axis direction). However, when the placement section 700 is moved to the routine maintenance position, the overlapping amount of the set Se placed in the placement section 700 and the placement section 700 itself with the corresponding developing module 31 becomes less than that in the case where the placement section 700 is located at the processing position, when viewed from the apparatus depth direction (X-axis direction). Therefore, by separating the exterior of the extension block BLC and moving the placement section 700 to the routine maintenance position, a worker can easily perform maintenance on the developing module 31 within the heating block G2 from the opposite side from the transfer space SP1.

When the placement section 700 is positioned at the major maintenance position, the set Se placed in the placement section 700 and the placement section 700 itself do not overlap with the corresponding developing module 31 at all, nor do they overlap a part or the whole of the side accommodation space SP3, when viewed from the apparatus depth direction (X-axis direction). Therefore, by separating the exterior of the extension block BLC and placing the placement section 700 at the major maintenance position, a worker can easily perform the maintenance on not only the developing module 31 in the heating block G2 but also a module inside the side accommodation space SP3 from the opposite side from the transfer space SP1.

Furthermore, in the above-described exemplary embodiment, among the developing modules 31 in the processing block 11, the one to which the developing fluid is supplied from the vaporizer 501 in the extension block BLC is the developing module 31 at the end portion on the opposite side (positive Y-axis side) from the carry-in/out block 10. Furthermore, when viewed from the apparatus depth direction (X-axis direction), the extension block BLC is provided only in the region overlapping the positive Y-axis end portion of the processing block 11, where the developing module 31 as the destination of the developing fluid is provided. Alternatively, among the developing modules 31 in the processing block 11, it may be the developing module 31 at an end portion on the carry-in/out block 10 side (negative Y-axis side) that is supplied with the developing fluid from the vaporizer 501 in the extension block BLC. Furthermore, the extension block BLC may be provided only in a region overlapping the negative Y-axis end portion of the processing block 11, where the developing module 31 as the destination of the developing fluid is provided, when viewed from the apparatus depth direction (X-axis direction). Alternatively, among the developing modules 31 in the processing block 11, the developing module 31 at each of the positive and negative Y-axis end portions may be supplied with the developing fluid from the vaporizer 501 in the extension block BLC. Furthermore, when viewed from the apparatus depth direction (X-axis direction), the extension block BLC may be provided in each of a region overlapping the positive Y-axis end portion of the processing block 11 and a region overlapping the negative Y-axis end portion of the processing block 11, where the developing modules 31 as the destinations of the developing fluid are located.

### Modification Examples

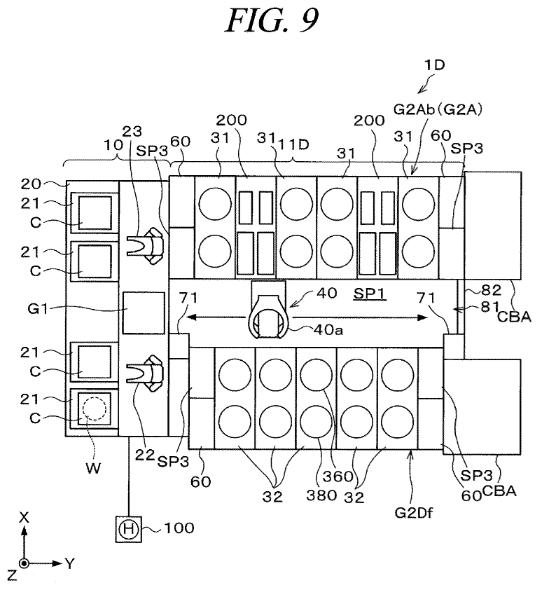

In the above-described exemplary embodiments, the front heating block G2f (G2Af) and the rear heating block G2b (G2Ab) include the same type of processing modules including the hot plates, that is, the developing modules 31. Alternatively, however, one of the front and rear heating blocks may be provided with a processing module including a hot plate other than the developing module 31. By way of example, as in a processing block 11D of a lithography apparatus 1D shown in FIG. 9, the developing module 31 may be provided in a rear heating block G2Ab as a processing module including a hot plate, and a PEB module 32 configured to perform a PEB process on the wafer W may be provided in the front heating block G2Df as a processing module including a hot plate. The PEB module 32 may have a cooling plate 380 in addition to a hot plate 360. If a processing module other than the developing module 31 is provided as a processing module including a hot plate in one of the front and rear heating blocks, the heating block in which the developing modules 31 are provided may have vaporization regions 200 between the developing modules 31 arranged in the apparatus width direction (Y-axis direction), the same as in the rear heating block G2Ab in FIG. 9.

Furthermore, when both the developing modules 31 and the PEB modules 32 are provided as processing modules including the hot plates, as in the lithography apparatus 1D in FIG. 9, the cassette C carried into the lithography apparatus accommodates, for example, the wafers W that have been exposed to light after being coated with a metal-containing resist film but have not been subjected to a PEB process. In the lithography apparatus 1D, the PEB process by the PEB module 32 and a development process by the developing module 31 are performed on each wafer W in this order. Here, the PEB process by the PEB module 32 may be performed multiple times (e.g., twice). In this case, different PEB modules 32 may be used for each PEB process.

Furthermore, the type of the processing modules including hot plates may be common between the front heating block and the rear heating block as a module (e.g., a PEB module) other than the developing module 31.

Furthermore, the type of the processing modules including hot plates may be different within at least one of the front and rear heating blocks. For example, both the developing module 31 and the PEB module 32 may be provided in at least one of the front and rear heating blocks.

In the above-described exemplary embodiments, a fluid containing a weak acid gas is used as the developing fluid. Instead, however, a fluid containing a weak acid mist may be used, or a fluid containing both a weak acid gas and a weak acid mist may be used. That is, the developing fluid according to the present disclosure is a fluid containing at least one of a weak acid gas and a weak acid mist.

Further, an ultraviolet irradiation module configured to irradiate the wafer W with ultraviolet rays may be disposed at a position accessible by any one of the transfer modules 22, 23, and 40 in the lithography apparatus. In this case, an ultraviolet irradiation processing is performed by the ultraviolet irradiation module on a wafer W having a metal-containing resist film formed thereon and subjected to an exposure process and a post-exposure bake (PEB) process. The ultraviolet irradiation processing here is a process of irradiating the entire top surface of the wafer W with ultraviolet rays. Specifically, it involves irradiating the entire surface of the wafer W with ultraviolet rays without a mask. Here, “the entire surface of the wafer W” includes at least the entire device formation region of the wafer W. The wavelength of the ultraviolet rays used in the ultraviolet irradiation processing is longer than that of EUV light, for example, equal to or greater than 100 nm and less than 300 nm. Further, the ultraviolet irradiation processing is performed in, for example, an atmospheric gas atmosphere.

Furthermore, an inspection module for inspecting a wafer W may be disposed at a position accessible by any one of the transfer modules 22, 23, and 40 in the lithography apparatus. In this case, a wafer W after being subjected to development by the developing module 31, for example, is transferred to and inspected by the inspection module. As a specific example, the entire top surface of the wafer W after being developed by the developing module 31 is imaged by the inspection module, and an image of the wafer W based on the imaged result is acquired by the controller 100.

In the above-described exemplary embodiments, the bottle containing an acid (specifically, acetic acid) is stored in the chemical box CB (CBA, CBB) as a source of the developing liquid. However, the bottle may be housed elsewhere (for example, in the carry-in/out block 10). Furthermore, the source of the developing liquid may be provided in a form other than a bottle within a factory where the lithography apparatus is located.

It should be noted that the above-described exemplary embodiments are illustrative in all aspects and are not anyway limiting. The above-described exemplary embodiments may be omitted, replaced and modified in various ways without departing from the scope and the spirit of claims. For example, the constitutional elements of the above-described exemplary embodiments may be combined in various ways. From any of these various combinations, functions and effects for the respective constituent elements are naturally obtained, and other functions and other effects obvious to those skilled in the art are also obtained from the description of the present specification.

In addition, the effects described in the present specification are only explanatory or illustrative and are not limiting. That is, the technique according to the present disclosure may exhibit, together with or instead of the above-stated effects, other effects obvious to those skilled in the art from the description of the present specification.

Further, the following configuration examples are also within the technical scope of the present disclosure.
(1) A lithography apparatus provided independently of an exposure apparatus, the lithography apparatus including:
a carry-in/out block having a placement section in which a receptacle accommodating multiple substrates is placed; and
a processing block including:
   multiple processing modules, each processing module including a hot plate;
   a transfer space that extends in an apparatus width direction from a side of the carry-in/out block and is provided with a transfer arm;
   a plurality of heating blocks in which the multiple processing modules are arranged in the apparatus width direction including a front heating block provided at a front side of the processing block and a rear heating block provided at a rear side of the processing block, the front heating block and the rear heating block facing each other with the transfer space therebetween, and
   an access opening for personnel into the transfer space.
(2) The lithography apparatus described in (1),
wherein at least one of the heating blocks has, as the processing module, a developing module performing development using a developing fluid including at least one of a weak acid gas or a weak acid mist having an acid dissociation constant (pKa) value of 4 or higher.
(3) The lithography apparatus described in (2),
wherein the at least one of the heating blocks has a plurality of developing modules and a fluid generation region between the developing modules arranged in the apparatus width direction,
a fluid generator generating the developing fluid from a developing liquid is provided at each of a first side and a second side within the fluid generation region in the apparatus width direction, and
the fluid generator is connected via a developing fluid supply line to the developing module facing the fluid generator in the apparatus width direction.
(4) The lithography apparatus described in (3),
wherein the heating blocks each having the developing module and the fluid generation region are stacked,
an accommodation space is provided below or above each of two vertically adjacent heating blocks each having the developing module and the fluid generation region, and
the lithography apparatus further includes a liquid supply line connecting the fluid generator provided in the fluid generation region of each of the two heating blocks to a source of the developing liquid, and
the liquid supply lie is housed, among the accommodation spaces, in the accommodation space closer to a boundary between the two vertically adjacent heating blocks.
(5) The lithography apparatus described in (4),
wherein the transfer arm is shared by the heating blocks,
the transfer arm includes a guide, and
the guide of the transfer arm is housed, among the accommodation spaces, in the accommodation space farther from the boundary. (6) The lithography apparatus described in any one of (1) to (5),
wherein the access opening is provided at an opposite side of the processing block from the carry-in/out block. (7) The lithography apparatus of (1), further comprising:
at least one extension block disposed adjacent to the processing block in an apparatus depth direction, the at least one extension block housing at least one fluid generator configured to supply a developing fluid to a developing module located in one of the front heating block or the rear heating block.
(8) the lithography apparatus of (7),
wherein the at least one extension block comprises a placement section on which the fluid generator is supported, the placement section being movable in the apparatus width direction between a processing position at which the placement section overlaps the developing module when viewed from the apparatus depth direction, a routine maintenance position at which the overlapping amount of the placement section with the developing module is reduced relative to the processing position, and a major maintenance position at which the placement section does not overlap the developing module when viewed from the apparatus depth direction.
(9) the lithography apparatus of (1),
wherein one of the front heating block or the rear heating block includes at least one developing module configured to develop a substrate using a developing fluid comprising at least one of a weak acid gas or a weak acid mist having an acid dissociation constant (pKa) value of 4 or higher, and
the other of the front heating block or the rear heating block includes at least one post-exposure bake module configured to perform a post-exposure bake process on the substrate.
(10) The lithography apparatus of (1), further comprising:
controller circuitry comprising a processor and a non-transitory storage medium storing instructions executable by the processor to control transfer operations of the transfer arm and processing operations of the processing modules in the heating blocks.
(11) The lithography apparatus of (2),
wherein the developing module further includes a cooling plate configured to regulate a temperature of a substrate positioned on the cooling plate, the cooling plate being configured to enable transfer of the substrate with respect to the hot plate.
(12) the lithography apparatus of (3),
wherein the fluid generator is disposed on a transfer space side of the heating block within the fluid generation region.
(13) The lithography apparatus of (1),
wherein the front heating block is provided in plurality, and
the rear heating block is provided in plurality.
(14) A method of processing substrates in a lithography apparatus provided independently of an exposure apparatus, the method comprising:
placing a receptacle accommodating multiple substrates on a placement section of a carry-in/out block of the lithography apparatus;
transferring, via a transfer arm provided in a transfer space extending in an apparatus width direction in a processing block of the lithography apparatus, a substrate from the receptacle to a processing module including a hot plate, wherein the processing module is located in one of a front heating block and a rear heating block, the front heating block and the rear heating block being disposed at a front side and a rear side, respectively, of the processing block and facing each other with the transfer space therebetween; and
processing the substrate on the hot plate within the processing module.
(15) The method of (14), wherein processing the substrate on the hot plate comprises:
developing the substrate by supplying, from a fluid generator connected to the processing module via a developing fluid supply line, a developing fluid comprising at least one of a weak acid gas or a weak acid mist having an acid dissociation constant (pKa) value of 4 or higher into the processing module.
(16) the method of (15),
wherein the fluid generator is disposed in a fluid generation region located between developing modules arranged in the apparatus width direction within at least one of the front heating block or the rear heating block, and
the fluid generator supplies the developing fluid to the developing module that faces the fluid generator in the apparatus width direction.
(17) The method of (14), further comprising:
accessing the transfer space through an access opening for personnel provided in the processing block; and
performing maintenance on the transfer arm or on one or more of the processing modules surrounding the transfer space.
(18) A non-transitory computer-readable medium storing instructions that, when executed by a processor of controller circuitry of a lithography apparatus provided independently of an exposure apparatus, cause the controller circuitry to perform operations comprising:
controlling a transfer arm provided in a transfer space that extends in an apparatus width direction in a processing block to transfer a substrate to a selected processing module including a hot plate, wherein the processing block has a front heating block and a rear heating block disposed at a front side and a rear side, respectively, of the processing block and facing each other with the transfer space therebetween, and wherein the selected processing module is located in one of the front heating block or the rear heating block; and
controlling the selected processing module to process the substrate on the hot plate.
(19) The non-transitory computer-readable medium of (18), wherein the operations further comprise:
controlling a fluid generator to generate a developing fluid from a developing liquid; and
controlling the selected processing module to develop the substrate by exposing the substrate to the developing fluid comprising at least one of a weak acid gas or a weak acid mist.
(20) The non-transitory computer-readable medium of (19), wherein the operations further comprise:
controlling a concentration sensor to measure a concentration of a weak acid in the developing fluid having an acid dissociation constant (pKa) value of 4 or higher; and
adjusting operation of the fluid generator based on the measured concentration to regulate the weak acid concentration of the developing fluid supplied to the selected processing module.

According to the exemplary embodiment, it is possible to improve the usability of the lithography apparatus.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim

1. A lithography apparatus provided independently of an exposure apparatus, the lithography apparatus comprising:
a carry-in/out block having a placement section in which a receptacle accommodating multiple substrates is placed; and
a processing block including:
multiple processing modules, each processing module including a hot plate;
a transfer space that extends in an apparatus width direction from a side of the carry-in/out block and is provided with a transfer arm;
a plurality of heating blocks in which the multiple processing modules are arranged in the apparatus width direction including a front heating block provided at a front side of the processing block and a rear heating block provided at a rear side of the processing block, the front heating block and the rear heating block facing each other with the transfer space therebetween; and
an access opening for personnel into the transfer space.

2. The lithography apparatus of claim 1,
wherein at least one of the heating blocks has, as the processing module, a developing module performing development using a developing fluid including at least one of a weak acid gas or a weak acid mist having an acid dissociation constant (pKa) value of 4 or higher.

3. The lithography apparatus of claim 2,
wherein the at least one of the heating blocks has a plurality of developing modules, and a fluid generation region between the developing modules arranged in the apparatus width direction,
a fluid generator generating the developing fluid from a developing liquid is provided at each of a first side and a second side within the fluid generation region in the apparatus width direction, and
the fluid generator is connected via a developing fluid supply line to the developing module facing the fluid generator in the apparatus width direction.

4. The lithography apparatus of claim 3,
wherein the heating blocks each having the developing module and the fluid generation region are stacked,
an accommodation space is provided below or above each of two vertically adjacent heating blocks each having the developing module and the fluid generation region, and
the lithography apparatus further includes a liquid supply line connecting the fluid generator provided in the fluid generation region of each of the two heating blocks to a source of the developing liquid, and
the liquid supply line is housed, among the accommodation spaces, in the accommodation space closer to a boundary between the two vertically adjacent heating blocks.

5. The lithography apparatus of claim 4,
wherein the transfer arm is shared by the heating blocks,
the transfer arm includes a guide, and
the guide of the transfer arm is housed, among the accommodation spaces, in the accommodation space farther from the boundary.

6. The lithography apparatus of claim 1,
wherein the access opening is provided at an opposite side of the processing block from the carry-in/out block.

7. The lithography apparatus of claim 1, further comprising:
at least one extension block disposed adjacent to the processing block in an apparatus depth direction, the at least one extension block housing at least one fluid generator configured to supply a developing fluid to a developing module located in one of the front heating block or the rear heating block.

8. The lithography apparatus of claim 7,
wherein the at least one extension block comprises a placement section on which the fluid generator is supported, the placement section being movable in the apparatus width direction between a processing position at which the placement section overlaps the developing module when viewed from the apparatus depth direction, a routine maintenance position at which the overlapping amount of the placement section with the developing module is reduced relative to the processing position, and a major maintenance position at which the placement section does not overlap the developing module when viewed from the apparatus depth direction.

9. The lithography apparatus of claim 1,
wherein one of the front heating block or the rear heating block includes at least one developing module configured to develop a substrate using a developing fluid comprising at least one of a weak acid gas or a weak acid mist having an acid dissociation constant (pKa) value of 4 or higher, and
the other of the front heating block or the rear heating block includes at least one post-exposure bake module configured to perform a post-exposure bake process on the substrate.

10. The lithography apparatus of claim 1, further comprising:
controller circuitry comprising a processor and a non-transitory storage medium storing instructions executable by the processor to control transfer operations of the transfer arm and processing operations of the processing modules in the heating blocks.

11. The lithography apparatus of claim 2,
wherein the developing module further includes a cooling plate configured to regulate a temperature of a substrate positioned on the cooling plate, the cooling plate being configured to enable transfer of the substrate with respect to the hot plate.

12. The lithography apparatus of claim 3,
wherein the fluid generator is disposed on a transfer space side of the heating block within the fluid generation region.

13. The lithography apparatus of claim 1,
wherein the front heating block is provided in plurality, and
the rear heating block is provided in plurality.

14. A method of processing substrates in a lithography apparatus provided independently of an exposure apparatus, the method comprising:
placing a receptacle accommodating multiple substrates on a placement section of a carry-in/out block of the lithography apparatus;
transferring, via a transfer arm provided in a transfer space extending in an apparatus width direction in a processing block of the lithography apparatus, a substrate from the receptacle to a processing module including a hot plate, wherein the processing module is located in one of a front heating block and a rear heating block, the front heating block and the rear heating block being disposed at a front side and a rear side, respectively, of the processing block and facing each other with the transfer space therebetween; and
processing the substrate on the hot plate within the processing module.

15. The method of claim 14, wherein processing the substrate on the hot plate comprises:
developing the substrate by supplying, from a fluid generator connected to the processing module via a developing fluid supply line, a developing fluid comprising at least one of a weak acid gas or a weak acid mist having an acid dissociation constant (pKa) value of 4 or higher into the processing module.

16. The method of claim 15,
wherein the fluid generator is disposed in a fluid generation region located between developing modules arranged in the apparatus width direction within at least one of the front heating block or the rear heating block, and
the fluid generator supplies the developing fluid to the developing module that faces the fluid generator in the apparatus width direction.

17. The method of claim 14, further comprising:
accessing the transfer space through an access opening for personnel provided in the processing block; and
performing maintenance on the transfer arm or on one or more of the processing modules surrounding the transfer space.

18. A non-transitory computer-readable medium storing instructions that, when executed by a processor of controller circuitry of a lithography apparatus provided independently of an exposure apparatus, cause the controller circuitry to perform operations comprising:
controlling a transfer arm provided in a transfer space that extends in an apparatus width direction in a processing block to transfer a substrate to a selected processing module including a hot plate, wherein the processing block has a front heating block and a rear heating block disposed at a front side and a rear side, respectively, of the processing block and facing each other with the transfer space therebetween, and wherein the selected processing module is located in one of the front heating block or the rear heating block; and
controlling the selected processing module to process the substrate on the hot plate.

19. The non-transitory computer-readable medium of claim 18, wherein the operations further comprise:
controlling a fluid generator to generate a developing fluid from a developing liquid; and
controlling the selected processing module to develop the substrate by exposing the substrate to the developing fluid comprising at least one of a weak acid gas or a weak acid mist.

20. The non-transitory computer-readable medium of claim 19, wherein the operations further comprise:
controlling a concentration sensor to measure a concentration of a weak acid in the developing fluid having an acid dissociation constant (pKa) value of 4 or higher; and
adjusting operation of the fluid generator based on the measured concentration to regulate the weak acid concentration of the developing fluid supplied to the selected processing module.
